(19) United States
(12) Patent Application Publication
(10) Pub. No.: US 2002/0104670 A1
(43) Pub. Date: Aug. 8, 2002

(54) Magnetic insulation for electronic devices

(76) Inventor: Richard Marmel, San Antonio, TX (US)

Correspondence Address: Cline H. White, JACKSON WALKER, LLP, 112 E. Pecan, Suite 2100, San Antonio, TX, 78205, US

(21) Appl. No.: 09/777,382

(22) Filed: Feb. 6, 2001

(51) Int. Cl. H05K 9/00

(52) U.S. Cl. 174/35 R

(57) ABSTRACT

The present invention incorporates multi-layered insulation that has at least one magnetized layer. The magnetized layer acts to insulate electronic devices, for example highly sensitive audio equipment, from electromagnetic interference and thus, increase the performance of such devices. In this manner, the output from electronic devices, particularly audio equipment, is improved and has less distortion and interference of the original source. A variety of products can be made from the described insulation walls in order to protect electronic device of varying shapes and sizes, as well as allow users of the present invention to choose the direction and orientation of such insulation.

### BACKGROUND OF THE INVENTION

1. Field of the Invention Applicants' invention relates to insulation for electronic devices. More particularly, it relates to insulation that incorporates a magnetized layer that acts to insulate electronic devices, particularly high-fidelity audio and other sensitive electronic equipment, from electromagnetic interference and thus, increase the performance of such devices.

2. Background Information Audio components, as well as other electronic output devices such as videocassette recorders and digital video disc players, are affected by electrical and magnetic fields. The interference created by these fields can adversely affect the output of the device. These waves may be introduced by the very wires and cables that supply power and connections to the device, or they may be the result of ambient electromagnetic fields or waves. Magnetized insulators have been used to remove or suppress the interference created by electromagnetic energy at the ends of electric wire that is connected to the electronic devices.

Generally, such insulation has been produced by wrapping the electric wires or cables with magnetic composites and coatings. These types of wire insulation allow the passage of signals along the conductive wire, but filter out the electromagnetic interference. Such insulation is particularly useful in applications where such interference impedes the performance of the electronic instruments to which the wire is connected.

However, electromagnetic waves can also affect the devices themselves, affecting the output in a negative manner. Therefore, it would be advantageous for an insulating device to be created for the electronic devices themselves in order to be able to limit the consequences of electromagnetic energy on the output of the device.

### SUMMARY OF THE INVENTION

The present invention incorporates a sheet-like material with multiple layers. It is the objective of the present invention to provide:

a. an apparatus for insulating electronic devices from electromagnetic interference;

b. an apparatus for improving the output performance of electronic devices, for example: audio components;

c. an apparatus configured to provide such insulation from all directions; and

d. an apparatus that may be configured and sized to insulate various types of electronic devices.

In order to solve the difficulties presented in attempting to obtain these objectives, an insulating apparatus has been developed which is designed for installation about the entire electrical component. There are many embodiments that may be used, that achieve these objects. However, the overall design criteria of the present invention dictate that the insulation provides a barrier in all directions to more completely block electromagnetic interference whose origin may be in any orientation. Additionally, there are a multitude of sizes and configurations in which the electronic devices are manufactured. Finally, a user may not, as a practical matter, be able to insulate all sides of the device, and must leave a side, or a portion thereof, open for access to the device by the user, connecting wires, desired electronic signals such as remote controls, and the like.

The present invention provides both an electrical resistance barrier and a magnetic field barrier to insulate the electronic device. The results are advantageous, particularly for those persons who are interested in improving the performance of their sensitive electrical equipment. By insulating audio devices with the present invention, the audio output has decreased distortion. While it might be expected that persons would employ the present invention for higher-end equipment, it can also be used to improve the output of lesser quality equipment.

In the case of digital equipment, such as compact disc players, the present invention can result in increased signal information. This is because digital equipment employ filters to eliminate or reduce electromagnetically, and in particular radio-frequency, induced distortion in the signal output. Unfortunately, some of the digital information is lost as the result of the filters. Because the present invention insulates the equipment from outside electromagnetic distortion, the digital filters are not activated and more information can be passed on as increased equipment sensitivity. Additionally, the digital filters are not perfect and therefore allow some magnetically induced distortion to pollute the output of the electrical device. When the present invention is utilized, the signal has less distortion bypassing the filters, and thus, both the quality and the quantity are improved. The present invention can improve the quality of many types of electronic equipment.

The present invention has a relatively weak magnetic field and can therefore, be placed in close proximity to the electrical device being insulated without itself causing distortion. It can also employ electrically resistive material, which can aid the insulation of stray electromagnetic interference. The magnetic field may generally be created by fixing at least two layers to one another. In a primary embodiment, at least one layer is made from a flexible, magnetic material, and the second layer being a flexible material. However, it is anticipated that various shielding cabinets could be manufactured incorporating the present invention wherein the sheeting would not need to be flexible. In this embodiment, the magnetic layer could be placed within the other layers of the cabinetry, thus moving the magnetic layer further from the electronic component. Additionally, the magnetic layer's thickness may be altered to fit design needs as set by the intended application. For example, the uses of a small personal stereo might require a lighter, more flexible embodiment, whereas a cabinet for a home stereo would allow for a heavier, more complete shielding wherein flexibility would not be as important.

Alternatively, the magnetic field may be created by embedding magnetized particles within a substrate. For the present invention, the substrate would consist of a flexible, sheet material, or flexible strips. The sheet may be connected together to form the desired configurations. Or, the strips may have an adhesive layer so that they can be adhered to one another to form the desired configurations.

The present invention attempts to maximize component shielding from electromagnetic interference, therefore, placing a shield layer on all sides of the component is recommended. Thus, an “envelope” or cabinet type embodiment is preferred, but, as with the thickness of the magnetic layer and the flexibility of the sheeting, the configuration of the present invention is variable and may be customized to the intended use.

The present invention can be manufactured in many sizes and configurations in order to custom fit a specific device, or it can be manufactured in general sizes to fit a number of devices. Generally, the operative embodiment of the present invention will incorporate a case-like structure covering the top, bottom, front, back, and sides of the device. Openings would allow access to the interior of the present invention so that the device could be placed within the case, and so that there is access to the electrical component for wiring and to controls by the user.

It is anticipated that the present invention could be “added on” or “built in” to an electronic component cabinet. If added on, individual shielding members would be fit around the electronic component, and placed in or around an external cabinet, if one is in use. If built in, the magnetic layers could be incorporated into the cabinet itself, making the shielding members “invisible,” inside the walls of the cabinet. For small, “personal” electronic devices that are designed to be portable or carried by the user, the present invention would be manufactured in an envelope type configuration and carried by the user.

It is also anticipated by the present invention that separate, single side pieces of insulation sheets be manufactured. In this way, the user can place insulation on specific sides of the device, to block specific electromagnetic interference sources, or if a full insulating case does not fit in the storage area. The individual insulation sheets may be manufactured to be removably attachable to one another on their edges by an attachment means, such as hook and loop fasteners, snaps, clips, adhesive, zipper, or the like.

The side members, whether in the embodiment of a single sheet or manufactured into a box-like or other shaped structure, may be manufactured as a single sheet of flexible or inflexible, magnetic material, or they may be manufactured from adhesive strips of flexible, magnetic material, that is connected in an overlapping configuration such that the desired structure is formed. Such strips are commercially available as magnetic tape. Using magnetic tape to form the structure of the insulation allows the manufacturer or user the flexibility of creating many different structure shapes specific to the item to be insulated. To create the desired shape, the manufacturer would adhere the strips of magnetic tape to each other, while overlapping them. In this manner, apertures may be formed where desired, thicknesses may be set, and adhesive surfaces, while holding the structure together, can be situated so as not to be exposed to the electrical component to be insulated. Examples of the configurations include, but are not limited to, envelopes or pouches for carrying personal stereo's, and box-like enclosures for portable stereos with openings for the speakers, wiring, and the like.

In summary, the present invention provides for electromagnetic shielding of electronic devices, but does so with flexibility in regard to configuration and manufacture.

### BRIEF DESCRIPTION OF THE DRAWINGS

FIG. 1 is a perspective view of the present invention.

FIG. 2 is another perspective view of the present invention.

FIG. 3 is a cross-section view of the present invention taken along line 1-1.

FIG. 3a is a cross-section view of an alternative embodiment of the present invention taken along line 1-1.

FIG. 4 is a perspective view illustrating a second embodiment of the present invention.

FIG. 5 is a front view of a third embodiment of the present invention showing individual walls in place against an electronic device.

FIG. 6 is a front view of the present invention within a cabinet.

FIG. 7 is a perspective view illustrating overlapping strips forming a fourth embodiment of the present invention.

### DETAILED DESCRIPTION OF THE PREFERRED EMBODIMENT

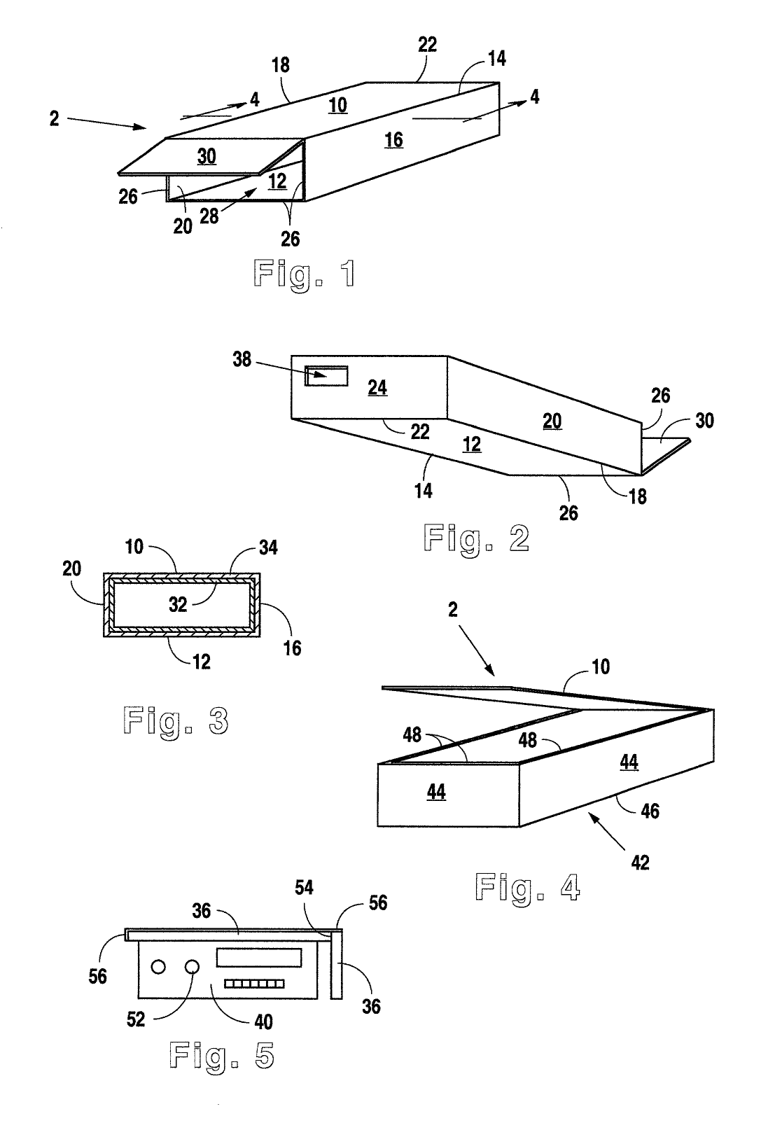

Referring to the figures, FIG. 1 shows a first embodiment from a generally front view of the present invention. The case (2) is generally box-like and consists of a top wall (10) and a bottom wall (12) connected at the first side edge(14) by a first side wall (16), the second side edge (18) by a second side wall (20), and the back edge (22) by a back side wall (24). The front edges (26) of the top wall (10), bottom wall (12), and side walls (16 and 20) from an aperture leading into the interior space (28) of the case (2). A front wall (30) adjoins the front edges (26) of the top wall (10), bottom wall (12), and side walls (16 and 20) enclosing the interior space (28). The front wall (30) may be removably, or rotatably attached to one or more of the front edges (26). With the front wall (30) removed or in an open position, the electronic device (40) may be inserted into the interior space (28). The front wall (30) may then be replaced, and the electronic device (40) insulated in all directions. Additionally, the removable front wall (30) provides access to the controls (52) of the electronic device (40) by the user (not shown).

FIG. 2 is a perspective view illustrating the present invention, generally showing the back. The embodiment of FIG. 1 is shown, but from this orientation, the aperture (38) that is used for access to the electronic device (40) by electrical wires or cables (not shown) is illustrated. The aperture (38) may be incorporated into the case (2) virtually anywhere in order to provide the easiest or most efficient access to the electronic device (40). Also shown are the back (24), second side (20), and bottom (12) walls, as well as the front wall (30).

FIG. 3 is a cross-section view of the present invention taken along line 1-1. It illustrates the layers (32,34) within the walls (10, 12, 16, and 20), as well as the layers within walls not shown (36 and 44). There are at least two (2) layers (32, 34), a first magnetized layer (32) fixed to a second layer (34). It is anticipated that there may be multiples of both the first magnetized layer (32), and the second layer (34), within the same wall (10, 12, 16, and 20), as well as the layers within walls not shown (36 and 44). It is further anticipated that layers (32 and 34) may be fixed in various orders. The first magnetized layer (32) provides the magnetic field to block electromagnetic interference, while the second layer (34) provides a substrate upon which the first magnetized layer (32) rests. The layers (32 and 34) further provide physical barriers to the outside elements for the electronic device (40). The first magnetized layer (32) may have a thickness that is varied according to manufacturing or use criteria.

FIG. 3a is a cross-section view of an alternative embodiment of the present invention taken along line 1-1. It illustrates the magnetized particles (35) embedded within the homogeneous layer (33). The amount of magnetized particles (35) within the homogeneous layer (33) can be varied in order to vary the strength of the magnetic field generated. Additional layers, such as an adhesive layer (not shown) may be added to strips (56) of the material incorporating the magnetized particles (35) embedded within the homogeneous layer (33) such as described in FIG. 7. Otherwise, the walls (10, 12, 16, and 20) made using this alternative embodiment can be configured as desired, and as described in FIG. 3.

FIG. 4 is a perspective view illustrating a second embodiment of the present invention. It is intended that the case (2) be manufactured in various sizes, shapes, and configurations in order to provide flexibility in fitting the case (2) to the electronic equipment (40). In this embodiment, the body (42) of the case (2) consists of the side walls (44) fixed at their bottom edge (46) to the bottom wall (12). Rather than having a movable front wall (30), the top wall (10) is removably, or rotatably, attached to one or more of the side wall (44) tope edges (48). This again creates a means for access to the electronic device (40).

FIG. 5 is a front view of a third embodiment of the present invention showing individual walls in place against an electronic device. Users (not shown) may also wish to take advantage of individual insulation sheets. Therefore, the present invention may also be manufactured in individual walls (36). The user (not shown) may place a wall (36) below, on top of, or on any side of the electronic device (40). Multiple walls (36) can be used in conjunction with one-another in order that the user can create an electromagnetic insulating compartment in a desired orientation. The walls (36) may be manufactured with connection means (54) at their edges (56) for removably connecting the walls (36) to one-another.

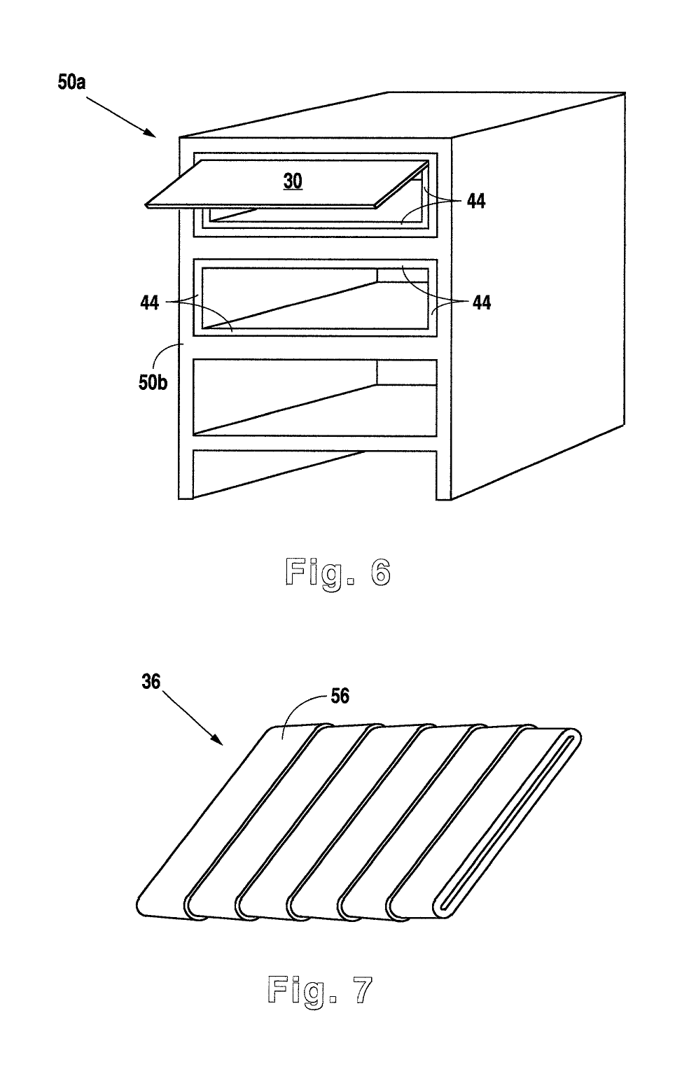

FIG. 6 is a front view of the present invention within a cabinet. The present invention may also be installed within a cabinet (50a). This may be achieved by affixing the case (2) or side walls (44) to the cabinet frame (50b), or using a substance to form the layers (32 and 34) which allows the cabinet frame (50b) itself to be made from the walls (36) of the present invention.

FIG. 7 is a perspective view illustrating overlapping flexible, magnetic strips (56) forming a fourth embodiment of the present invention. The strips (56) have a layer of adhesive that is used to adhere the strips to (56) each other in an overlapping fashion. In this manner, wall (36) such as shown in FIG. 5, and each of the configurations shown in all of the figures, may be manufactured. The overlapping strip (56) construction technique may be expanded to form any configuration desired by the user (not shown), or required by a specific electronic device (40) to be insulated.

Although the invention has been described with reference to specific embodiments, this description is not meant to be construed in a limited sense. Various modifications of the disclosed embodiments, as well as alternative embodiments of the inventions will become apparent to persons skilled in the art upon the reference to the description of the invention. It is, therefore, contemplated that the appended claims will cover such modifications that fall within the scope of the invention.

I claim:

1. A case for electromagnetically insulating an electronic device having controls and electrical wires extending from said electronic device for connection to other devices, comprising:
a top wall and a bottom wall, each of substantially rectangular shape, superimposed upon one another;
said top wall connected to said bottom wall at their first side edges by a first side wall;
said top wall connected to said bottom wall at their second side edges by a second side wall;
said top wall connected to said bottom wall at their back edges by a back wall;
a front edge of each of said top wall, said bottom wall, said first side wall, and said second side wall defining an aperture through which said electronic device may be passed;
said case sized to accept said electronic device within said case's interior space;
said case having apertures located so as to allow access to said electronic device by said electric wires; and
said top, bottom, first side, second side, and back walls having more than one layer fixed to one another, at least one of said layers being magnetized.

2. The case of claim 1, further comprising:
a front wall removably connected to said top wall and said bottom wall at their front side edges;
said front wall having apertures located so as to allow access to said controls of said electronic device by said electric wires; and
said front wall having more than one layer fixed to one another, at least one of said layers being magnetized.

3. The case of claim 1, further comprising:
said top wall rotatably connected at its front side edge to a front wall; and
said front wall having more than one layer fixed to one another, at least one of said layers being magnetized.

4. The apparatus of claim 1, further comprising:
said bottom wall rotatably connected at its front side edge to a front wall; and
said front wall having more than one layer fixed to one another, at least one of said layers being magnetized.

5. The apparatus of claim 1, further comprising:
said top, bottom, first side, second side, and back walls being flexible.

6. The case of claim 1, wherein said case is fixed within a cabinet.

7. A case of generally box structure for electromagnetically insulating an electronic device having controls and electrical wires extending from said electronic device for connection to other devices, said case comprising:
a body comprising a bottom wall, and four side walls attached to said bottom wall along said side walls' bottom edges;
said side walls having top edges defining an opening;
a top wall removably attached to said side wall top edges;
said body having apertures located so as to allow access to said controls and access to said electronic device by said electric wires;
said top, bottom, and side walls having more than one layer fixed to one another, at least one of said layers being magnetized; and
said top, bottom, and side walls further comprised of overlapping strips of flexible, magnetic strips each having an adhesive layer.

8. A wall member for electromagnetically insulating an electronic device comprised of:
two or more layers fixed to one another, at least one of said layers being magnetized; and
said layers being flexible.

9. The wall member of claim 8, wherein said wall member has a connection means at its edges making said wall removably attachable at its edges to other like walls.

10. The wall member of claim 8, wherein said wall member is further comprised of overlapping strips of flexible, magnetic strips each having an adhesive layer.

11. A wall member for electromagnetically insulating an electronic device comprised of:
a homogeneous layer having magnetized particles embedded therein;
said homogeneous layer having an adhesive layer; and
said homogeneous layer being flexible.

12. The wall member of claim 11, wherein said wall member is further comprised of:
overlapping strips of said homogeneous layer.
